(19) United States
(12) Patent Application Publication
(10) Pub. No.: US 2026/0349253 A1
(43) Pub. Date: Nov. 5, 2026

(54) OPTICAL ELEMENT AND EXPOSURE SYSTEM

(71) Applicants: Interface Advanced Technology (Chengdu) Co., Ltd., Chengdu (CN); Interface Technology (ChengDu) Co., Ltd., Chengdu (CN); INTERFACE OPTOELECTROICS (SHENZHEN) CO., LTD., Shenzhen (CN); GENERAL INTERFACE SOLUTION LIMITED, ZHUNAN (TW)

(72) Inventors: CHUN-MING CHEN, Hsinchu (TW); CHIH-HAO CHEN, New Taipei (TW)

(21) Appl. No.: 19/125,547

(22) PCT Filed: May 13, 2024
(86) PCT No.: PCT/CN2024/092942

§ 371 Date: Apr. 29, 2025

(51) Int. Cl. G02B 27/01; G02B 27/42

(52) U.S. Cl. CPC G02B 27/0172; G02B 27/4222; G02B 2027/0118; G02B 2027/0174

(57) ABSTRACT

An optical element, including a transparent substrate, a reflective layer, and at least one transmissive-reflective layer. The transparent substrate includes a first surface and a second surface opposite to the first surface. The reflective layer is disposed on the second surface, and the reflective layer is used to reflect light. At least one transmissive-reflective layer is disposed between the reflective layer and the first surface. The transmissive-reflective layer is used to receive the incident light transmitted from the first surface, and the reflective layer and the transmissive-reflective layer are used together to modulate the incident light transmitted from the first surface into output light, and to project the output light from the first surface. The output light includes multiple sub-output beams emitted from different positions of the transmissive-reflective layer, and the light intensity of each sub-output beam is different. An exposure system using the aforementioned optical element is also provided.

### FIELD

The subject matter herein relates to field of holographic optics, especially to an optical element and an exposure system using the optical element.

### BACKGROUND

With the advancement of science and technology, more and more optical devices have adopted holographic optical elements, such as Augmented Reality (AR) head-mounted display devices. Currently, a mainstream exposure method for holographic optical elements involves using a beam splitter to divide the light emitted from a laser source into two incident beams with uniform illumination and equal intensity. The two beams interfere on a photosensitive layer of a film, forming alternating bright and dark interference fringes on the photosensitive material. This causes the refractive index distribution of the photosensitive layer to change according to the fringes, ultimately forming a refractive index modulation grating, thus creating a holographic optical element. The exposure amount of the light incident on the photosensitive material determines the diffraction efficiency, diffraction bandwidth, and other optical diffraction properties of the holographic optical element, where the exposure amount is related to the exposure time and illumination (i.e., light intensity).

Since the two incident beams have the same intensity, the diffraction efficiency of the completed holographic optical element is the same at different positions. In an AR head-mounted display device, this holographic optical element is used as an out-coupling grating on a side of the optical waveguide near the human eye. The holographic optical element is used to couple out the light transmitted by the optical waveguide, forming image light that enters the human eye. However, because the diffraction efficiency of the holographic optical element is the same at different positions, the light intensity will attenuate due to reflections between the holographic optical element and the optical waveguide, causing the light intensity on the output side to gradually decrease. This results in uneven brightness in the image received by the human eye.

### SUMMARY

A first aspect of the present disclosure provides an optical element, including:
a transparent substrate, including a first surface and a second surface opposite to the first surface;
a reflective layer, disposed on the second surface, the reflective layer being used to reflect light; and
at least one transmissive-reflective layer, disposed between the reflective layer and the first surface, the transmissive-reflective layer being configured for transmitting part of light and reflecting part of the light, the reflective layer and the transmissive-reflective layer being used together to modulate the incident light transmitted from the first surface into output light, and to project the output light from the first surface;
wherein, the output light includes multiple sub-output beams emitted from different positions of the transmissive-reflective layer, and the light intensity of each sub-output beam is different.

The optical element provided by the embodiments of the present disclosure, by setting a reflective layer and at least one transmissive-reflective layer, allows part of the light incident from the first surface to be reflected back to the first surface, and part of the light to be transmitted to the reflective layer and reflected back to the transmissive-reflective layer. The transmissive-reflective layer then transmits part of the light and reflects part of the light again, causing the output light emitted from the first surface to include multiple sub-output beams with different light intensities. The reflective layer and the transmissive-reflective layer together modulate the incident light into multiple sub-output beams with different light intensities. The optical element can effectively emit multiple sub-output beams with different light intensities. When the optical element is used in an exposure system, the output light emitted from the first surface interferes with other light incident on the film. Since the sub-output beams emitted from the optical element have different light intensities, the light incident on the film also has different light intensities, meaning the exposure amount at different positions on the film varies. By exposing the film with the light incident on the film and the sub-output beams, a holographic optical element with different diffraction efficiencies at different positions can be produced. When the holographic optical element is applied to an AR head-mounted display device, the holographic optical element with different diffraction efficiencies at different positions is used as an out-coupling grating on the side of the optical waveguide near the human eye to counteract the attenuation of light intensity on the output side, thereby improving the uneven brightness of the AR head-mounted display device.

In one embodiment, the reflective layer and the transmissive-reflective layer are parallel.

In one embodiment, the second surface includes a first sub-side surface and a second sub-side surface intersecting with the first sub-side surface, the reflective layer covers the first sub-side surface and the second sub-side surface, and the angle between the first sub-side surface and the second sub-side surface ranges from 0° to 180°.

In one embodiment, the second surface is inclined relative to the first surface, and the angle between the first surface and the second surface ranges from 0° to 90°.

In one embodiment, each sub-output beam emitted from the first surface is approximately parallel, and the spacing between the sub-output beams is positively correlated with the distance between the reflective layer and the transmissive-reflective layer.

In one embodiment, the ratio of the transmittance to the reflectance of the transmissive-reflective layer ranges from 0 to 100.

In one embodiment, the optical element is an integrally formed structure.

In one embodiment, the transparent substrate includes several sub-transparent substrate parts, and the at least one transmissive-reflective layer and the reflective layer are respectively formed on different sub-transparent substrate parts, so that the at least one transmissive-reflective layer and the reflective layer are separated by the sub-transparent substrate parts, and the sub-transparent substrate parts are spliced together.

In one embodiment, when there are two or more transmissive-reflective layers, each transmissive-reflective layer is located at a different distance from the reflective layer.

A second aspect of the present disclosure provides an exposure system, including:
a light source module, including a first light source, the first light source being used to emit incident light;
the optical element according to any of the aforementioned embodiments; and
a film, disposed on one side of the optical element, the film being used to receive the output light emitted from the first surface;
wherein, the optical element is used to modulate the incident light into the output light, and the output light is emitted from the first surface and projected onto the film.

The exposure system provided by the embodiments of the present disclosure, by setting the optical element according to any of the aforementioned embodiments, allows the output light emitted from the first surface to interfere with other light incident on the film. Since the sub-output beams emitted from the optical element have different light intensities, the light incident on the film also has different light intensities, meaning the exposure amount at different positions on the film varies. By exposing the film with the light incident on the film and the sub-output beams, a holographic optical element with different diffraction efficiencies at different positions can be produced. When the holographic optical element is applied to an AR head-mounted display device, the holographic optical element with different diffraction efficiencies at different positions is used as an out-coupling grating on the side of the optical waveguide near the human eye to counteract the attenuation of light intensity on the output side, thereby improving the uneven brightness of the AR head-mounted display device.

In one embodiment, the film includes a substrate and a photosensitive layer disposed on one side of the substrate, the photosensitive layer being used to receive the output light.

In one embodiment, the first light source is configured to emit the incident light, which is modulated by the optical element and then emitted as output light from the first surface. Multiple sub-output beams emitted from different positions along a first direction parallel to the first surface are incident on the photosensitive layer, and the sub-output beams at least partially overlap in the first direction, causing the brightness of the light spot formed by the output light on the photosensitive layer to increase along the first direction.

In one embodiment, the first light source is configured to emit the incident light, which is modulated by the optical element and then emitted as output light from the first surface. Multiple sub-output beams emitted from different positions along a first direction parallel to the first surface are incident on the photosensitive layer, and the sub-output beams do not overlap with each other, causing the brightness of the light spot formed by the output light on the photosensitive layer to decrease along the first direction.

In one embodiment, the incident light and the output light emitted from the first surface interfere on the photosensitive layer, forming interference fringes on the photosensitive layer.

In one embodiment, the light source module further includes an auxiliary light source, the auxiliary light source being used to emit auxiliary light, the auxiliary light being incident on the film, and the auxiliary light and the output light interfere on the photosensitive layer, forming interference fringes on the photosensitive layer.

### BRIEF DESCRIPTION OF THE DRAWINGS

FIG. 1 is a schematic three-dimensional structure diagram of the optical element according to a first embodiment of the present disclosure.

FIG. 2 is a cross-sectional view along line II-II of FIG. 1.

FIG. 3 is a schematic diagram of light path of light incident on an optical element and light emitted from the optical element according to the first embodiment.

FIG. 4 is a schematic diagram of the first spacing and the second spacing according to one embodiment.

FIG. 5 is a schematic diagram of the sub-output beams at least partially overlapping in the first direction according to one embodiment.

FIG. 6 is a schematic three-dimensional structure diagram of the optical element according to a second embodiment of the present disclosure.

FIG. 7 is a cross-sectional view along line VII-VII of FIG. 6.

FIG. 8 is a schematic diagram of the light path of the light incident on the optical element and the light emitted from the optical element according to the second embodiment.

FIG. 9 is a schematic three-dimensional structure diagram of the optical element according to the third embodiment of the present disclosure.

FIG. 10 is a schematic diagram of the light path of the light incident on the optical element and the light emitted from the optical element according to the third embodiment.

FIG. 11 is a schematic structural diagram of the exposure system according to one embodiment.

FIG. 12 is a schematic diagram of the light path of the film and the optical element in the exposure system according to one embodiment.

FIG. 13 is a schematic structural diagram of another embodiment of the exposure system.

### DESCRIPTION OF SYMBOLS OF MAIN COMPONENTS

| | |
|---|---|
| Optical Element | 100, 200, 300 |
| Transparent Substrate | 10 |
| First Surface | 1 |
| Second Surface | 2 |
| First Sub-Side Surface | 21 |
| Second Sub-Side Surface | 22 |
| Sub-Transparent Substrate Part | 11 |
| First Sub-Transparent Substrate Part | 111 |
| Second Sub-Transparent Substrate Part | 112 |
| Third Sub-Transparent Substrate Part | 113 |
| Reflective Layer | 3 |
| Transmissive-Reflective Layer | 5 |
| First Transmissive-Reflective Layer | 51 |
| Second Transmissive-Reflective Layer | 52 |
| Incident Light | LR |
| Output Light | LF |
| Sub-Output Beam | LF0 |
| First Sub-Output Beam | LF1 |
| Second Sub-Output Beam | LF2 |
| Third Sub-Output Beam | LF3 |
| Nth Sub-Output Beam | LFn |
| Auxiliary Light | L2 |
| Exposure System | 400, 500 |
| Light Source Module | 40 |
| First Light Source | 401 |
| Auxiliary Light Source | 402 |
| Film | 41 |
| Substrate | 411 |
| Photosensitive Layer | 413 |
| Shutter | 42 |
| Phase Retarder | 43 |
| Beam Splitter | 44 |
| Spatial Filter | 45 |
| Aperture Stop | 46 |
| Collimating Lens | 47 |
| First Angle | α |
| Second Angle | β |
| First Spacing | H1 |
| Second Spacing | H2 |
| First Direction | X |
| First Region | A |
| Second Region | B |
| Third Region | C |
| Nth Region | N |

The following specific embodiments will further illustrate the present disclosure in conjunction with the above drawings.

### DETAILED DESCRIPTION

The following will provide a clear and complete description of the technical solution in the embodiments of the present disclosure, in conjunction with the accompanying drawings. Obviously, the described embodiments are only a part of the embodiments of the present disclosure, not all of them.

Unless otherwise defined, all technical and scientific terms used in the present disclosure have the same meanings as those commonly understood by those skilled in the technical field of the present disclosure. The terms used in the specification of the present disclosure are only for the purpose of describing specific embodiments and are not intended to limit the present disclosure.

In order to further elaborate on the technical means and effects adopted to achieve the intended purpose of the present disclosure, the following is a detailed explanation of the present disclosure, combined with the accompanying drawings and preferred implementation methods.

More and more optical devices (such as AR head-mounted display devices) have adopted holographic optical elements. A method for preparing holographic optical elements includes using an exposure system for exposure. Currently, the mainstream exposure method for holographic optical elements involves using a beam splitter to divide the light emitted from a laser source into two incident beams with uniform illumination and equal intensity. The two beams interfere on a photosensitive layer of a film, forming alternating bright and dark interference fringes on the photosensitive material. This causes a refractive index distribution of the photosensitive layer to change according to the fringes, ultimately forming a refractive index modulation grating, thus creating a holographic optical element. The exposure amount of the light incident on the photosensitive material determines the diffraction efficiency, diffraction bandwidth, and other optical diffraction properties of the holographic optical element.

The present disclosure provides an optical element used in an exposure system and an exposure system having the optical element. The optical element is used to adjust the light intensity distribution of the exposure system on the element to be exposed (such as a film with a photosensitive layer for forming a holographic optical element), so that different regions of the element to be exposed receive different exposure amounts under the same exposure time.

### Embodiment 1

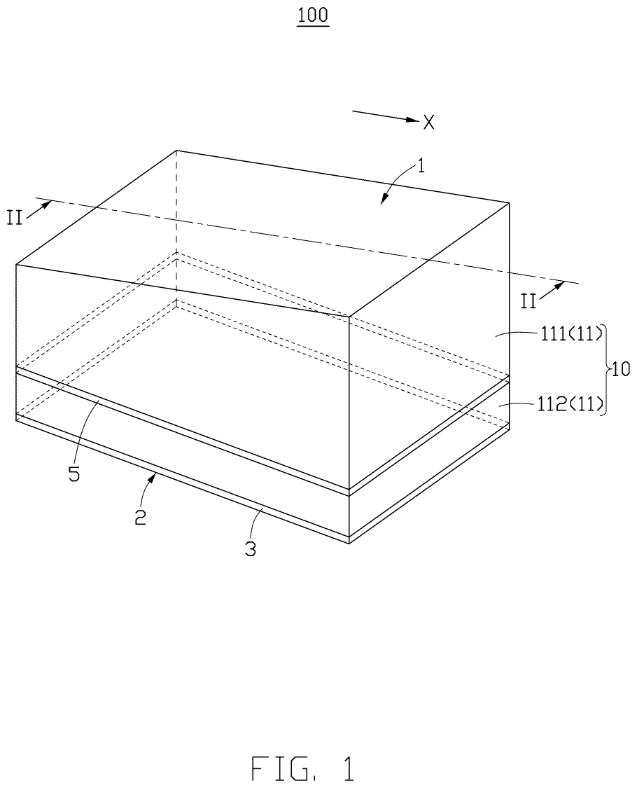

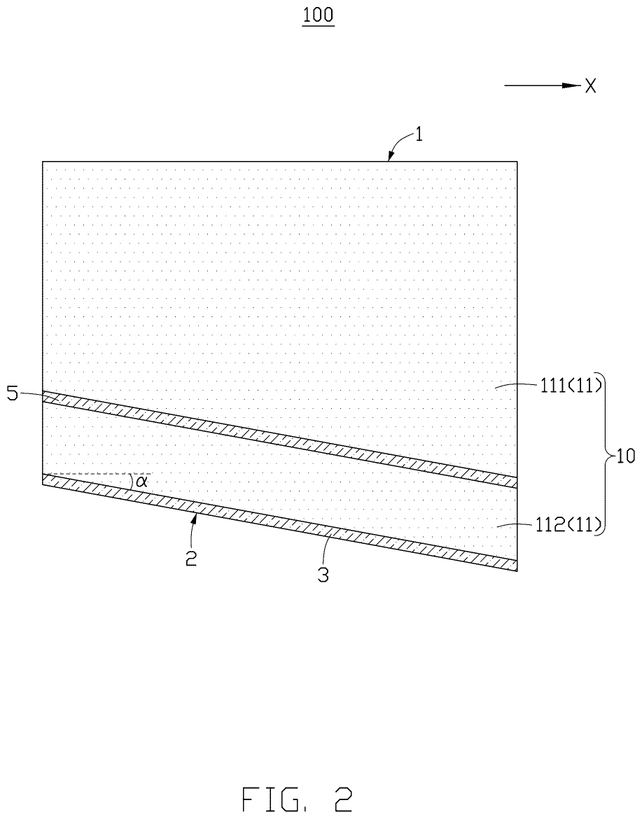

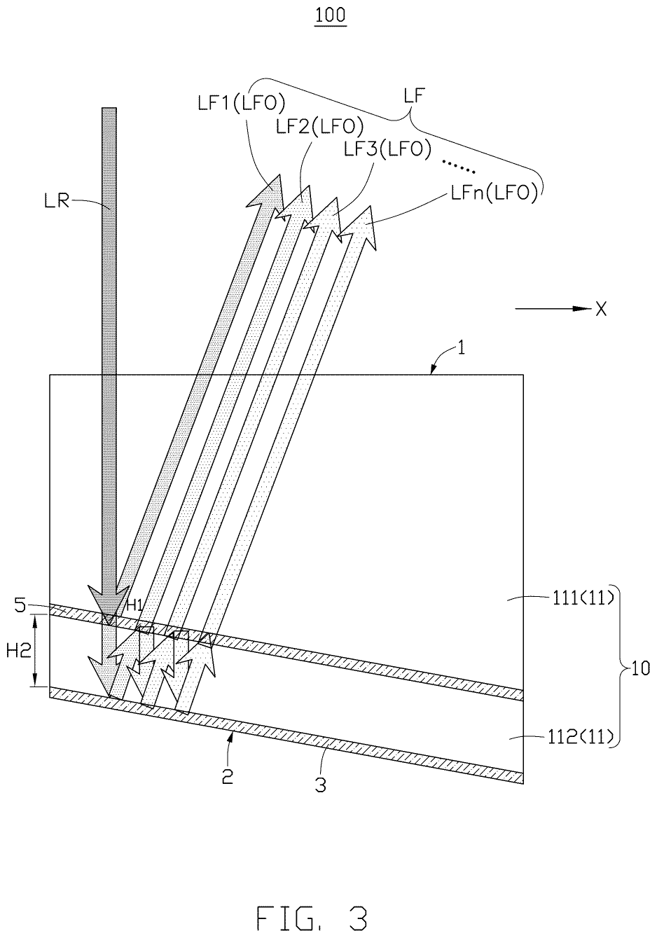

Please refer to FIG. 1, FIG. 2, and FIG. 3 together. The optical element of this embodiment includes a transparent substrate 10, a reflective layer 3, and a transmissive-reflective layer 5. The transparent substrate 10 includes a first surface 1 and a second surface 2 opposite to the first surface 1. The reflective layer 3 is disposed on the second surface 2, and the reflective layer 3 is used to reflect light. In this embodiment, a number of the transmissive-reflective layer 5 is one, which is disposed between the reflective layer 3 and the first surface 1. The transmissive-reflective layer 5 can transmit part of light and reflect part of the light. The transmissive-reflective layer 5 receives incident light LR transmitted from the first surface 1, and the reflective layer 3 and the transmissive-reflective layer 5 together modulate the incident light LR transmitted from the first surface 1 into output light LF, and project the output light LF from the first surface 1. The output light LF includes a plurality of sub-output beams LF0 emitted from different positions of the transmissive-reflective layer 5, and the light intensity of each sub-output beam LF0 is different.

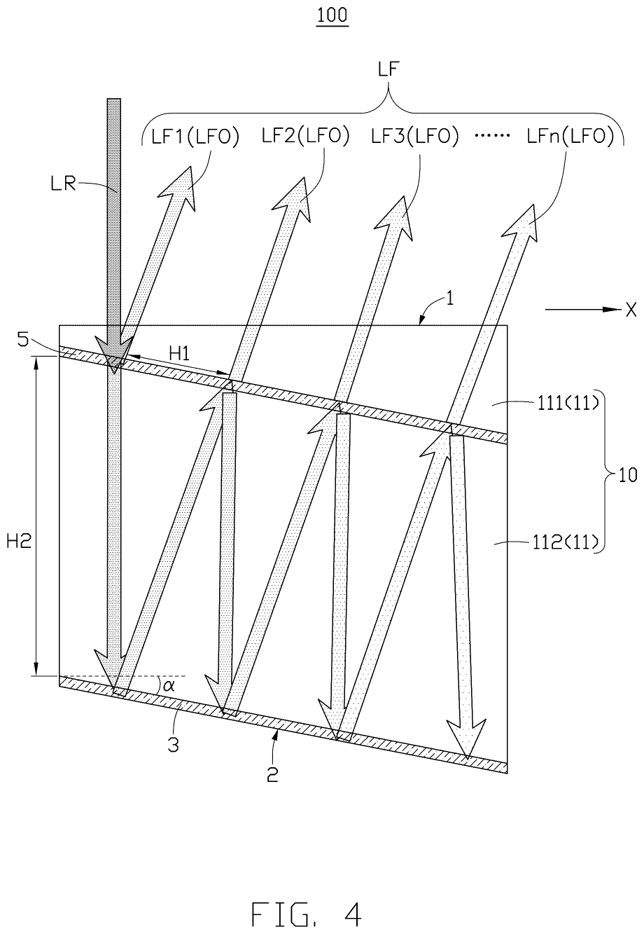

Please refer to FIGS. 3 and 4 together. The second surface 2 is inclined relative to the first surface 1. A angle between the first surface 1 and the second surface 2 is defined as a first angle α, and a range of the first angle α is 0°-90°. For example, the first angle α can be 0°-30°, 30°-60°, or 60°-90°. It should be noted that the first angle α cannot be 0° or 90°. The reflective layer 3 and the transmissive-reflective layer 5 are parallel to each other (completely parallel or approximately parallel), and the parallelism error between the reflective layer 3 and the transmissive-reflective layer 5 is less than 5°. When the parallelism error between the reflective layer 3 and the transmissive-reflective layer 5 exceeds 5°, it will affect the emission position of each sub-output beam LF0 on the first surface 1, for example, the sub-output beams LF0 will no longer be emitted at equal intervals. Each sub-output beam LF0 emitted from the first surface 1 is approximately parallel, and the sub-output beams LF0 are emitted at approximately equal intervals. A spacing between adjacent sub-output beams LF0 is defined as a first spacing H1, and a spacing between the reflective layer 3 and the transmissive-reflective layer 5 is defined as a second spacing H2. The first spacing H1 is positively correlated with the second spacing H2. When the second spacing H2 is increased, the first spacing H1 between adjacent sub-output beams LF0 also increases; when the second spacing H2 is decreased, the first spacing H1 between adjacent sub-output beams LF0 also decreases.

In this embodiment, the reflective layer 3 is a metal reflective film coated on the second surface 2. For example, when the incident light LR is in the ultraviolet band, aluminum can be selected as the material for the metal reflective film. When the incident light LR is in the visible light band, aluminum and silver can be used as the materials for the metal reflective film. When the incident light LR is in the infrared band, gold, silver, or copper is commonly used as the material for the metal reflective film. The metal reflective film has the advantages of a large extinction coefficient and stable optical properties. In other embodiments, the reflective layer 3 can also be a fully dielectric reflective film or a combination of a metal reflective film and a fully dielectric reflective film, which is not limited in the present disclosure.

A transmittance of the transmissive-reflective layer 5 is a ratio of the luminous flux of the incident light LR transmitted through the transmissive-reflective layer 5 to the luminous flux of the incident light LR incident on the transmissive-reflective layer 5. A reflectance of the transmissive-reflective layer 5 is the ratio of the luminous flux of the incident light LR reflected by the transmissive-reflective layer 5 to the luminous flux of the incident light LR incident on the transmissive-reflective layer 5. Specifically, the ratio of the transmittance to the reflectance of the transmissive-reflective layer 5 ranges from 0 to 100. It should be noted that when the ratio of the transmittance to the reflectance of the transmissive-reflective layer 5 is 0 or 100, the transmissive-reflective layer 5 is fully reflective or fully transmissive, so the ratio of the transmittance to the reflectance of the transmissive-reflective layer 5 cannot be 0 or 100. In this embodiment, the transmissive-reflective layer 5 is a semi-transparent and semi-reflective film, with a transmittance of 50% and a reflectance of 50%. In other embodiments, the transmittance and reflectance of the transmissive-reflective layer 5 can also be other values, such as a transmittance of 70% and a reflectance of 30%, or a transmittance of 60% and a reflectance of 40%, which is not limited in the present disclosure.

In this embodiment, the optical element 100 is an integrally formed structure. For example, the transmissive-reflective layer 5 and the reflective layer 3 can first be fixed in a mold, and then the material forming the transparent substrate 10 can be injected into the mold by injection molding to combine with the transmissive-reflective layer 5 and the reflective layer 3. In other embodiments, the transparent substrate 10 includes several sub-transparent substrate parts 11 (such as the first sub-transparent substrate part 111 and the second sub-transparent substrate part 112) spliced together. The transmissive-reflective layer 5 and the reflective layer 3 are respectively formed on different sub-transparent substrate parts 11, so that the transmissive-reflective layer 5 and the reflective layer 3 are separated by the sub-transparent substrate parts 11. The sub-transparent substrate parts 11 with the transmissive-reflective layer 5 or the reflective layer 3 can be spliced together by adhesive bonding. For example, a metal material combined with silicon dioxide can first be used to coat the transmissive-reflective layer 5 on one side of the first sub-transparent substrate part 111, and the reflective layer 3 can be formed on one side of the second sub-transparent substrate part 112. The side of the first sub-transparent substrate part 111 with the transmissive-reflective layer 5 can be bonded to the side of the second sub-transparent substrate part 112 away from the reflective layer 3 with an adhesive (not shown), such as an optical transparent adhesive. In this embodiment, material of the transparent substrate 10 is glass, which has good light transmission performance, thermal stability, and low dispersion. In other embodiments, the material of the transparent substrate 10 of the optical element 100 can also be polyethylene terephthalate (PET), polycarbonate (PC), or polymethyl methacrylate (PMMA). The materials of the first sub-transparent substrate part 111 and the second sub-transparent substrate part 112 can be the same or different, which is not limited in the present disclosure. The material of the transparent substrate 10 is not limited to the above materials, and any light-transmitting material can be used for the transparent substrate 10, which is not limited in the present disclosure. It should be noted that “light-transmitting” refers to a high transmittance of light of specific wavelengths (especially visible light, infrared, and ultraviolet bands).

Please refer to FIG. 3 again. Specifically, when illumination of the incident light LR on the first surface 1 is small, that is, when luminous flux of the incident light LR per unit area is small, the multiple sub-output beams LF0 emitted from different positions of the transmissive-reflective layer 5 do not overlap, causing the multiple sub-output beams LF0 emitted from different positions of the transmissive-reflective layer 5 to decrease in light intensity along the first direction X parallel to the first surface 1. For example, when the transmittance of the transmissive-reflective layer 5 is 50% and the reflectance is 50%, the output light LF includes the first sub-output beam LF1, the second sub-output beam LF2, the third sub-output beam LF3, and the nth sub-output beam LFn. The incident light LR is incident on the transmissive-reflective layer 5 from the first surface 1, and the transmissive-reflective layer 5 transmits part of the light and reflects part of the light. 50% of the light intensity of the incident light LR is reflected back to the first surface 1 by the transmissive-reflective layer 5, that is, the first sub-output beam LF1 is emitted from the transmissive-reflective layer 5 to the first surface 1, and the light intensity of the first sub-output beam LF1 is 50% of the original incident light LR. The remaining 50% of the light intensity of the incident light LR is transmitted to the reflective layer 3 by the transmissive-reflective layer 5, and the reflective layer 3 reflects the 50% light intensity of the incident light LR back to the transmissive-reflective layer 5. The transmissive-reflective layer 5 transmits part of the light and reflects part of the light again. 25% of the light intensity of the incident light LR is reflected back to the reflective layer 3 by the transmissive-reflective layer 5, and the remaining 25% of the light intensity of the incident light LR can be transmitted through the transmissive-reflective layer 5, that is, the second sub-output beam LF2 is emitted from the transmissive-reflective layer 5, and the light intensity of the second sub-output beam LF2 is 25% of the original incident light LR. 25% of the light intensity of the incident light LR is reflected back to the reflective layer 3 by the transmissive-reflective layer 5, and the reflective layer 3 reflects the 25% light intensity of the incident light LR back to the transmissive-reflective layer 5. The transmissive-reflective layer 5 transmits part of the light and reflects part of the light again. 12.5% of the light intensity of the incident light LR is reflected back to the reflective layer 3 by the transmissive-reflective layer 5, and the remaining 12.5% of the light intensity of the incident light LR can be transmitted through the transmissive-reflective layer 5, that is, the third sub-output beam LF3 is emitted from the transmissive-reflective layer 5, and the light intensity of the second sub-output beam LF2 is 12.5% of the original incident light LR. That is, when the transmittance of the transmissive-reflective layer 5 is 50% and the reflectance is 50%, the light intensity En1 of the nth sub-output beam LFn satisfies the following formula (1):

$$E n 1 = \frac{100}{{2}^{n + 1}} \% \qquad \# ( 1 )$$

where n is greater than 2, and light intensity of the (n+1)th sub-output beam is half of the light intensity En1 of the nth sub-output beam LFn. When the transmittance and reflectance of the transmissive-reflective layer 5 take other values, the above sub-light intensities will change accordingly. The present application does not impose limitations on this.

TABLE 1
light intensity of different region

| | Light | Light | Total |
|---|---|---|---|
| | intensity of the | intensity of the | Light |
| Region | incident light | sub-output beam | Intensity |
| First Region A | 100% | 50% | 150% |
| Second Region B | 100% | 75% | 175% |
| Third Region C | 100% | 87.5% | 187.5% |
| Nth Region N | 100% | En2 | 100% + En2 |

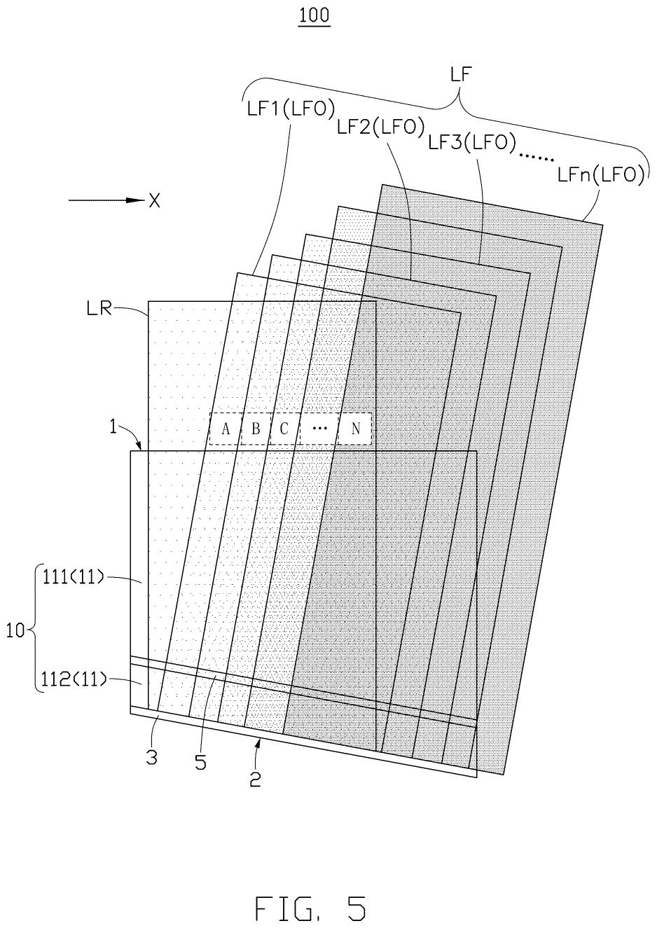

Please refer to Table 1 and FIG. 5. When illumination of the incident light LR on the first surface 1 is large, that is, when the luminous flux of the incident light LR per unit area is large, the multiple sub-output beams LF0 emitted from different positions of the transmissive-reflective layer 5 overlap, causing the multiple sub-output beams LF0 emitted from different positions of the transmissive-reflective layer 5 to increase in light intensity along the first direction X parallel to the first surface 1. For example, when the transmittance of the transmissive-reflective layer 5 is 50% and the reflectance is 50%, the output light LF includes the first sub-output beam LF1, the second sub-output beam LF2, the third sub-output beam LF3, and the nth sub-output beam LFn. The incident light LR is incident on the transmissive-reflective layer 5 from the first surface 1, and the transmissive-reflective layer 5 transmits part of the light and reflects part of the light. 50% of the light intensity of the incident light LR is reflected back to the first surface 1 by the transmissive-reflective layer 5, that is, the first sub-output beam LF1 is emitted from the transmissive-reflective layer 5 to the first surface 1, and the light intensity of the first sub-output beam LF1 is 50% of the original incident light LR. The total light intensity in the first region A on the side of the first surface 1 away from the second surface 2 is the sum of the light intensity of the incident light LR and the light intensity of the first sub-output beam LF1, that is, the total light intensity is 150% of the light intensity of the incident light LR. The first region A in FIG. 4 is a virtual region (shown by dashed lines), not a real region. 50% of the light intensity of the incident light LR is transmitted to the reflective layer 3 by the transmissive-reflective layer 5, and the reflective layer 3 reflects the 50% light intensity of the incident light LR back to the transmissive-reflective layer 5. The transmissive-reflective layer 5 transmits part of the light and reflects part of the light again. 25% of the light intensity of the incident light LR is reflected back to the reflective layer 3 by the transmissive-reflective layer 5, and the remaining 25% of the light intensity of the incident light LR can be transmitted through the transmissive-reflective layer 5, that is, the second sub-output beam LF2 is emitted from the transmissive-reflective layer 5 to the first surface 1. Since the luminous flux of the second sub-output beam LF2 overlaps with that of the first sub-output beam LF1, the light intensity of the second sub-output beam LF2 in the second region B on the side of the first surface 1 away from the second surface 2 is 75% of the light intensity of the incident light LR. The total light intensity in the second region B is the sum of the light intensity of the incident light LR, the light intensity of the first sub-output beam LF1, and the light intensity of the second sub-output beam LF2, that is, the total light intensity is 175% of the light intensity of the incident light LR. The second region B in FIG. 4 is a virtual region (shown by dashed lines), not a real region. 25% of the light intensity of the incident light LR is reflected back to the reflective layer 3 by the transmissive-reflective layer 5, and the reflective layer 3 reflects the 25% light intensity of the incident light LR back to the transmissive-reflective layer 5. The transmissive-reflective layer 5 transmits part of the light and reflects part of the light again. 12.5% of the light intensity of the incident light LR is reflected back to the reflective layer 3 by the transmissive-reflective layer 5, and the remaining 12.5% of the light intensity of the incident light LR can be transmitted through the transmissive-reflective layer 5, that is, the third sub-output beam LF3 is emitted from the transmissive-reflective layer 5. Since the luminous flux of the third sub-output beam LF3 overlaps with that of the second sub-output beam LF2, the first sub-output beam LF1, and the incident light LR, the light intensity of the third sub-output beam LF3 in the third region C on the side of the first surface 1 away from the second surface 2 is 75% of the light intensity of the incident light LR. The total light intensity in the third region C is the sum of the light intensity of the incident light LR, the light intensity of the first sub-output beam LF1, the light intensity of the second sub-output beam LF2, and the light intensity of the third sub-output beam LF3, that is, the total light intensity is 187.5% of the light intensity of the incident light LR. The third region C in FIG. 4 is a virtual region (shown by dashed lines), not a real region. That is, when the transmittance of the transmissive-reflective layer 5 is 50% and the reflectance is 50%, the light intensity En2 of the nth sub-output beam LFn satisfies the following formula (2):

$$En 2 = 50 \% + 25 \% + 12.5 \% + … + \frac{100}{{2}^{n + 1}} \% \qquad \# ( 2 )$$

The total light intensity in the nth region N is the sum of the light intensity of the incident light LR, the light intensity of the first sub-output beam LF1, the light intensity of the second sub-output beam LF2, and the light intensity of the nth sub-output beam LFn, that is, the total light intensity is 100%+En2. Where n is greater than 2, when the transmittance and reflectance of the transmissive-reflective layer 5 are other values, the light intensity values of the sub-output beams will also change accordingly, which is not limited in the present disclosure.

The optical element 100 provided by the embodiments of the present disclosure, by setting a reflective layer 3 and a transmissive-reflective layer 5, allows part of the light incident from the first surface 1 to be reflected back to the first surface 1, and part of the light to be transmitted to the reflective layer 3 and reflected back to the transmissive-reflective layer 5. The transmissive-reflective layer 5 then transmits part of the light and reflects part of the light again, causing the output light LF emitted from the first surface 1 to include multiple sub-output beams LF0 with different light intensities. The reflective layer 3 and the transmissive-reflective layer 5 together modulate the incident light LR into multiple sub-output beams LF0 with different light intensities. The optical element 100 can effectively emit multiple sub-output beams LF0 with different light intensities. When the optical element 100 is used in an exposure system, the output light LF emitted from the first surface 1 interferes with other light incident on the film. Since the sub-output beams LF0 emitted from the optical element 100 have different light intensities, the light incident on the film also has different light intensities, meaning the exposure amount at different positions on the film varies. By exposing the film with the light incident on the film and the sub-output beams LF0, a holographic optical element with different diffraction efficiencies at different positions can be produced. When the holographic optical element is applied to an AR head-mounted display device, the holographic optical element with different diffraction efficiencies at different positions is used as an out-coupling grating on the side of the optical waveguide near the human eye to counteract the attenuation of light intensity on the output side, thereby improving the uneven brightness of the AR head-mounted display device.

### Embodiment 2

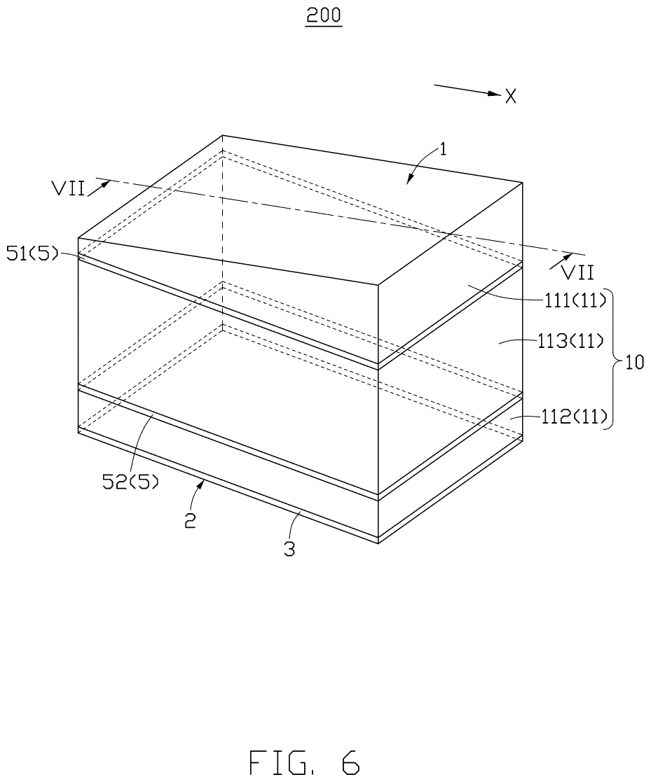

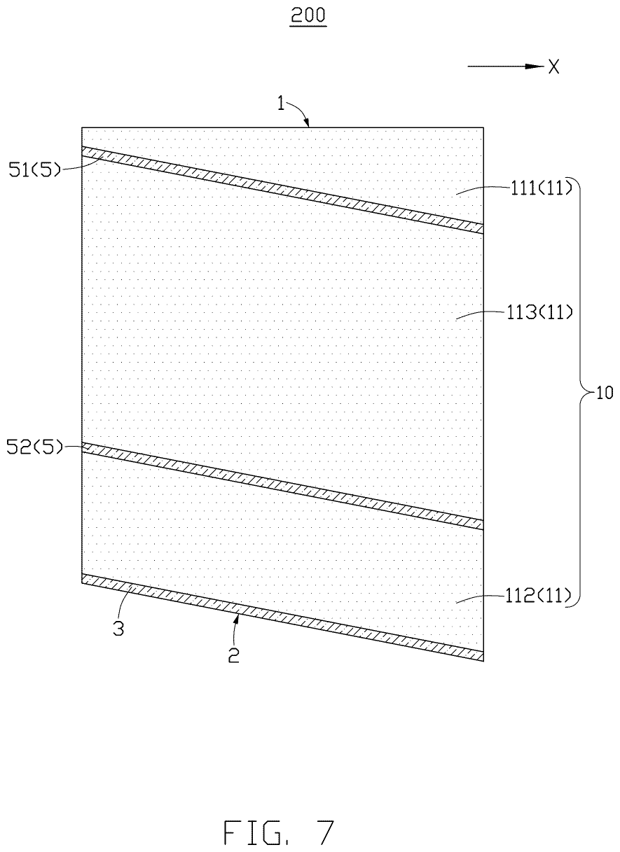

Please refer to FIG. 6 and FIG. 7 together. The optical element 200 of this embodiment differs from the optical element 100 of the first embodiment in that the optical element 200 includes a reflective layer 3 and two transmissive-reflective layers 5, which are divided into a first transmissive-reflective layer 51 and a second transmissive-reflective layer 52. In other embodiments, the optical element 200 can also include more transmissive-reflective layers 5, such as three or four transmissive-reflective layers 5, which is not limited in the present disclosure. When there are two or more transmissive-reflective layers 5, each transmissive-reflective layer 5 is located at a different distance from the reflective layer 3.

The reflective layer 3 is disposed on the second surface 2, and the first transmissive-reflective layer 51, the second transmissive-reflective layer 52, and the reflective layer 3 are parallel to each other (completely parallel or approximately parallel). The parallelism error between the first transmissive-reflective layer 51, the second transmissive-reflective layer 52, and the reflective layer 3 is less than 5°. When the parallelism error between the reflective layer 3 and the transmissive-reflective layer 5 exceeds 5°, it will affect the emission position of each sub-output beam LF0 on the first surface 1, for example, the sub-output beams LF0 will no longer be emitted at equal intervals.

In this embodiment, the optical element 200 is an integrally formed structure, and its forming method is the same as that of the first embodiment. In other embodiments, the transparent substrate 10 includes several sub-transparent substrate parts 11 (such as the first sub-transparent substrate part 111, the second sub-transparent substrate part 112, and the third sub-transparent substrate part 113) spliced together. The transmissive-reflective layer 5 and the reflective layer 3 are respectively formed on different sub-transparent substrate parts 11, so that the transmissive-reflective layer 5 and the reflective layer 3 are separated by the sub-transparent substrate parts 11. The sub-transparent substrate parts 11 with the transmissive-reflective layer 5 or the reflective layer 3 can be spliced together by adhesive bonding. Specifically, the first transmissive-reflective layer 51 is located between the first sub-transparent substrate part 111 and the second sub-transparent substrate part 112, and the second transmissive-reflective layer 52 is located between the second sub-transparent substrate part 112 and the third sub-transparent substrate part 113. The reflective layer 3 is formed on the side of the third sub-transparent substrate part 113 away from the second transmissive-reflective layer 52. The materials of the first sub-transparent substrate part 11, the second sub-transparent substrate part 12, and the third sub-transparent substrate part 13 can be the same or different, which is not limited in the present disclosure.

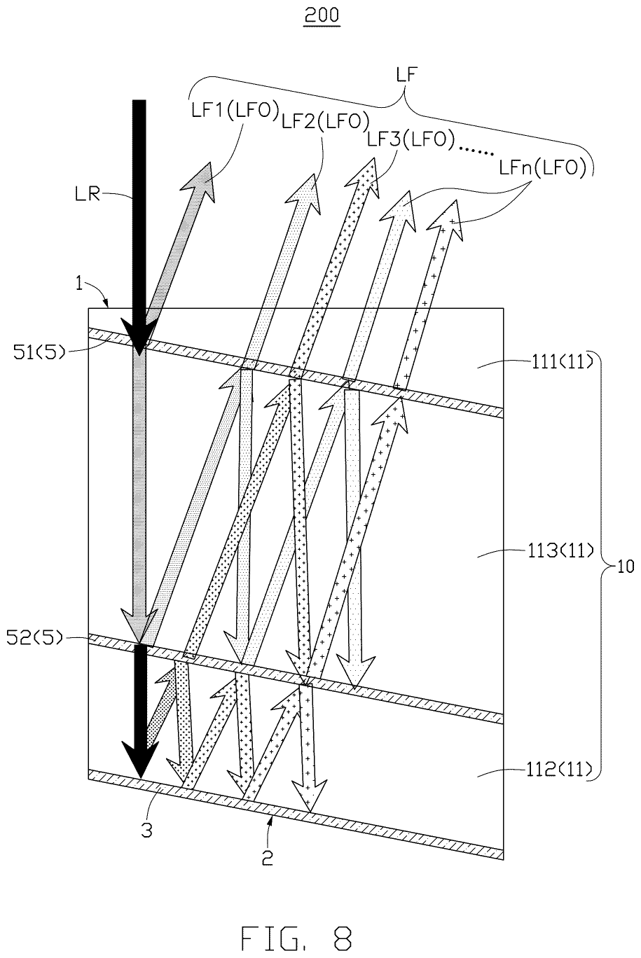

Please refer to FIG. 8. The light incident on the first transmissive-reflective layer 51 from the first surface 1 is partially reflected back to the first surface 1, and partially transmitted to the second transmissive-reflective layer 52 and reflected back to the first transmissive-reflective layer 51. The first transmissive-reflective layer 51 then transmits part of the light and reflects part of the light again. The light transmitted to the second transmissive-reflective layer 52 is partially reflected back to the first transmissive-reflective layer 51 and partially transmitted to the reflective layer 3 and reflected back to the second transmissive-reflective layer 52. The second transmissive-reflective layer 52 then transmits part of the light and reflects part of the light again, causing the output light LF emitted from the first surface 1 to include multiple sub-output beams LF0 with different light intensities. The reflective layer 3, the first transmissive-reflective layer 51, and the second transmissive-reflective layer 52 together modulate the incident light LR into multiple sub-output beams LF0 with different light intensities, such as the first sub-output beam LF1, the second sub-output beam LF2, the third sub-output beam LF3, and the nth sub-output beam LFn. For example, when the transmittance of the transmissive-reflective layer 5 is 50% and the reflectance is 50%, the incident light LR is incident on the first transmissive-reflective layer 51 from the first surface 1, and 50% of the light intensity of the incident light LR is transmitted to the second transmissive-reflective layer 52 by the first transmissive-reflective layer 51. 50% of the light intensity of the incident light LR is emitted from the first surface 1, that is, the first sub-output beam LF0 is emitted. The 50% light intensity of the incident light LR transmitted to the second transmissive-reflective layer 52 is partially transmitted and partially reflected by the second transmissive-reflective layer 52. 25% of the light intensity of the incident light LR is reflected back to the first transmissive-reflective layer 51, and 25% of the light intensity of the incident light LR is transmitted to the reflective layer 3. The 25% light intensity of the incident light LR reflected back to the first transmissive-reflective layer 51 is transmitted to the first surface 1 by the first transmissive-reflective layer 51 and emitted, that is, the second sub-output beam LF0 is emitted. Therefore, when the number of transmissive-reflective layers 5 is increased, the difference in light intensity between adjacent sub-output beams LF0 becomes larger compared to when there is only one transmissive-reflective layer 5, that is, the trend of light intensity attenuation of the sub-output beams LF0 emitted from different positions is increased.

The optical element 200 provided by the embodiments of the present disclosure, by setting a reflective layer 3 and two transmissive-reflective layers 5, allows the reflective layer 3, the first transmissive-reflective layer 51, and the second transmissive-reflective layer 52 to together modulate the incident light LR into multiple sub-output beams LF0 with different light intensities. The incident light LR undergoes multiple reflections and transmissions between the reflective layer 3, the first transmissive-reflective layer 51, and the second transmissive-reflective layer 52, causing the output light LF emitted from the first surface 1 to include multiple sub-output beams LF0 with different light intensities. More sub-output beams LF0 with different light intensities can be obtained, and the optical element 200 can effectively emit multiple sub-output beams LF0 with different light intensities. When the optical element 200 is used in an exposure system, the output light LF emitted from the first surface 1 interferes with other light incident on the film. Since the sub-output beams LF0 emitted from the optical element 200 have different light intensities, the light incident on the film also has different light intensities, meaning the exposure amount at different positions on the film varies. By exposing the film with the light incident on the film and the sub-output beams LF0, a holographic optical element with different diffraction efficiencies at different positions can be produced. When the holographic optical element is applied to an AR head-mounted display device, the holographic optical element with different diffraction efficiencies at different positions is used as an out-coupling grating on the side of the optical waveguide near the human eye to counteract the attenuation of light intensity on the output side, thereby improving the uneven brightness of the AR head-mounted display device.

### Embodiment 3

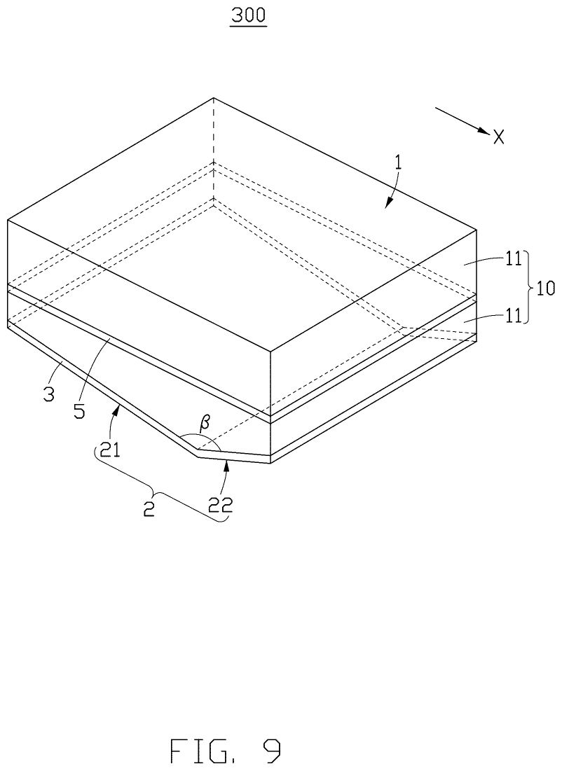

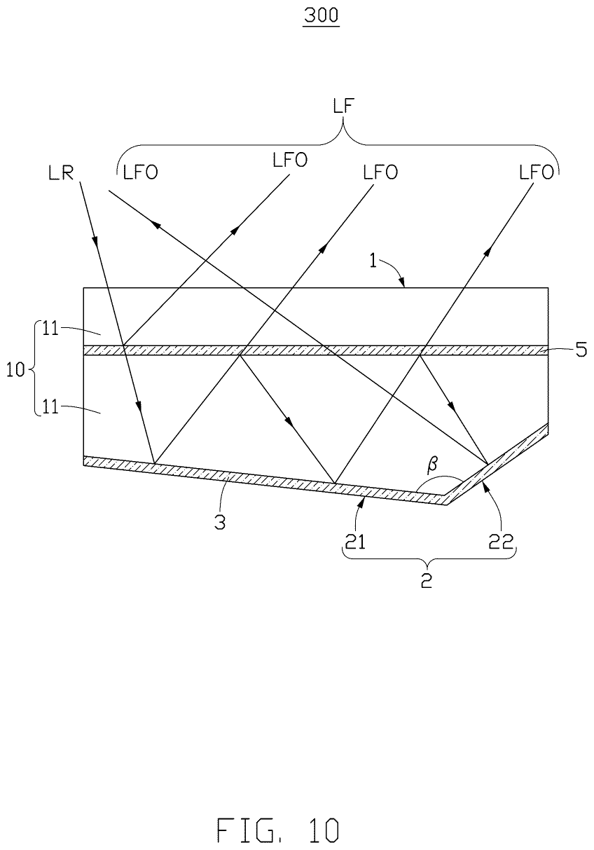

Please refer to FIG. 9 and FIG. 10 together. The optical element 300 of this embodiment differs from the optical element 100 of the first embodiment in that the second surface 2 includes a first sub-side surface 21 and a second sub-side surface 22 intersecting with the first sub-side surface 21, and the reflective layer 3 covers the first sub-side surface 21 and the second sub-side surface 22. The angle between the first sub-side surface 21 and the second sub-side surface 22 is defined as the second angle β, and the range of the second angle β is 0°-180° (for example, 0°-30°, 30°-60°, 60°-90°, 90°-120°, 120°-150°, or) 150°-180°. It should be noted that the second angle β cannot be 0° or 180°. Specifically, when the second surface 2 includes the first sub-side surface 21 and the second sub-side surface 22 with a certain angle, since the first sub-side surface 21 and the second sub-side surface 22 have an angle, the output light LF emitted from the transmissive-reflective layer 5 to the first surface 1 includes at least two sub-output beams LF0 emitted at different angles, and the light intensity of each sub-output beam LF0 is different, and at least two sub-output beams LF0 with different light intensities overlap.

The optical element 200 provided by the third embodiment of the present disclosure, by setting the first sub-side surface 21 and the second sub-side surface 22 with an angle, allows the output light LF emitted from different positions of the transmissive-reflective layer 5 to include at least two sub-output beams LF0 emitted at different angles, effectively emitting at least two sub-output beams LF0 with different emission directions and light intensities. When the optical element 300 is used in an exposure system, the output light LF emitted from the first surface 1 interferes with other light incident on the film. Since the sub-output beams LF0 emitted from the optical element 300 have different light intensities, the light incident on the film also has different light intensities, meaning the exposure amount at different positions on the film varies. By exposing the film with the light incident on the film and the sub-output beams LF0, a holographic optical element with different diffraction efficiencies at different positions can be produced. When the holographic optical element is applied to an AR head-mounted display device, the holographic optical element with different diffraction efficiencies at different positions is used as an out-coupling grating on the side of the optical waveguide near the human eye to counteract the attenuation of light intensity on the output side, thereby improving the uneven brightness of the AR head-mounted display device.

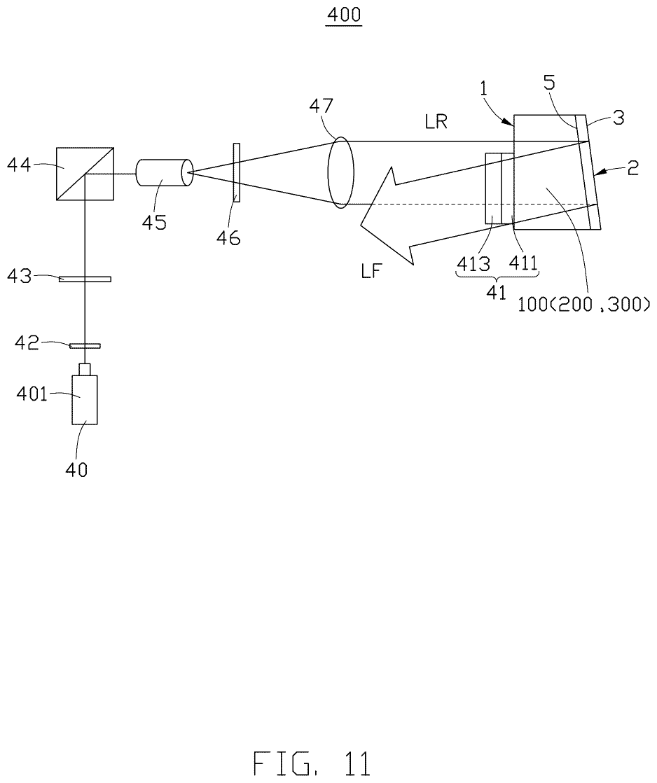

Please refer to FIG. 11. A exposure system 400 (500) of this embodiment includes a light source module 40, the optical element (100, 200, 300) according to any of the aforementioned embodiments, and a film 41. The light source module 40 includes a first light source 401, which is used to emit incident light LR. The first light source 401 can be a gas laser, solid-state laser, semiconductor laser, fiber laser, or dye laser. The film 41 is disposed on one side of the optical element (100, 200, 300), and the film 41 is used to receive the output light LF emitted from the first surface 1. The optical element (100, 200, 300) is used to modulate the incident light LR into output light LF, and the output light LF is emitted from the first surface 1 and projected onto the film 41. The film 41 includes a substrate 411 and a photosensitive layer 413 disposed on one side of the substrate 411, and the photosensitive layer 413 is used to receive the output light LF. The photosensitive layer 413 can be disposed on the side of the substrate 411 close to or away from the optical element (100, 200, 300), which is not limited in the present disclosure.

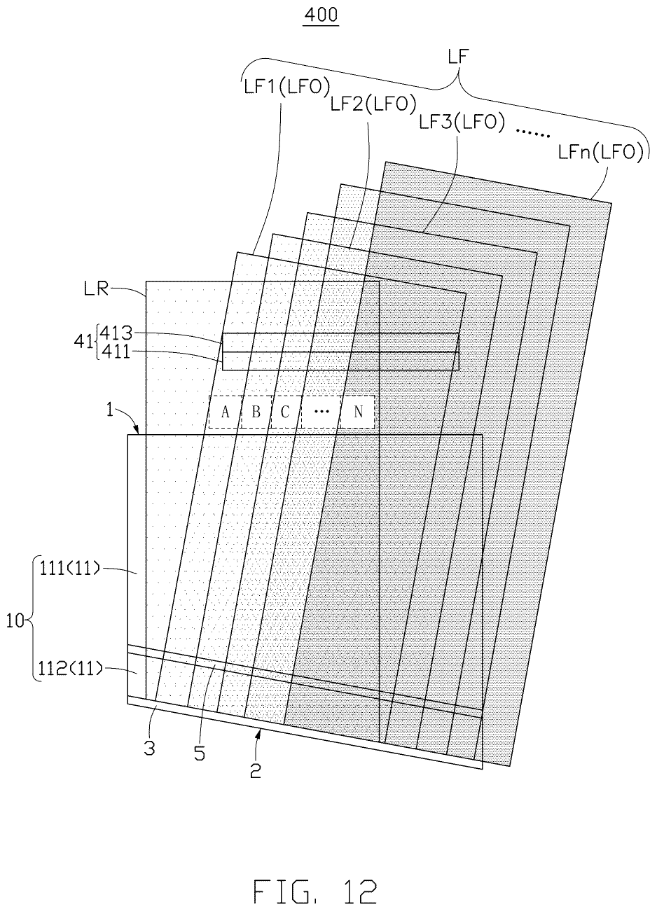

Please refer to FIG. 11 and FIG. 12 together. In the exposure system 400 of this embodiment, the incident light LR and the output light LF emitted from the first surface 1 interfere on the photosensitive layer 413, forming interference fringes on the photosensitive layer 413. Multiple sub-output beams LF0 emitted from different positions along the first direction X parallel to the first surface 1 are incident on the photosensitive layer 413. The first light source 401 is configured to emit the incident light LR, which is modulated by the optical element (100, 200, 300) and then emitted as output light LF from the first surface 1. Multiple sub-output beams LF0 emitted from different positions along the first direction X parallel to the first surface 1 are incident on the photosensitive layer 413, and the sub-output beams at least partially overlap in the first direction X, causing the brightness of the light spot formed by the output light LF on the photosensitive layer 413 to increase along the first direction X. The output light LF and the incident light LR at least partially overlap and interfere on the photosensitive layer 413 of the film 41, forming alternating bright and dark interference fringes on the photosensitive layer 413. This causes the refractive index distribution of the photosensitive layer 413 to change according to the fringes, ultimately forming a refractive index modulation grating inside the photosensitive layer 413 material, thus creating a holographic optical element. Since the multiple sub-output beams LF0 incident on the photosensitive layer 413 have different light intensities, the exposure amount at different positions on the film 41 also varies, resulting in different diffraction efficiencies at different positions of the holographic optical element. For example, when the transmittance of the transmissive-reflective layer 5 is 50% and the reflectance is 50%, the output light LF includes the first sub-output beam LF1, the second sub-output beam LF2, the third sub-output beam LF3, and the nth sub-output beam LFn. The incident light LR is incident on the transmissive-reflective layer 5 from the first surface 1, and the transmissive-reflective layer 5 transmits part of the light and reflects part of the light. 50% of the light intensity of the incident light LR is reflected back to the first surface 1 by the transmissive-reflective layer 5, that is, the first sub-output beam LF1 is emitted from the transmissive-reflective layer 5 to the first surface 1, and the light intensity of the first sub-output beam LF1 is 50% of the original incident light LR. The total light intensity in the first region A on the side of the first surface 1 away from the second surface 2 is the sum of the light intensity of the incident light LR and the light intensity of the first sub-output beam LF1, that is, the total light intensity is 150% of the light intensity of the incident light LR. The first region A in FIG. 9 is a virtual region (shown by dashed lines), not a real region. 50% of the light intensity of the incident light LR is transmitted to the reflective layer 3 by the transmissive-reflective layer 5, and the reflective layer 3 reflects the 50% light intensity of the incident light LR back to the transmissive-reflective layer 5. The transmissive-reflective layer 5 transmits part of the light and reflects part of the light again. 25% of the light intensity of the incident light LR is reflected back to the reflective layer 3 by the transmissive-reflective layer 5, and the remaining 25% of the light intensity of the incident light LR can be transmitted through the transmissive-reflective layer 5, that is, the second sub-output beam LF2 is emitted from the transmissive-reflective layer 5 to the first surface 1. Since the luminous flux of the second sub-output beam LF2 overlaps with that of the first sub-output beam LF1, the light intensity of the second sub-output beam LF2 in the second region B on the side of the first surface 1 away from the second surface 2 is 75% of the light intensity of the incident light LR. The total light intensity in the second region B is the sum of the light intensity of the incident light LR, the light intensity of the first sub-output beam LF1, and the light intensity of the second sub-output beam LF2, that is, the total light intensity is 175% of the light intensity of the incident light LR. The second region B in FIG. 9 is a virtual region (shown by dashed lines), not a real region. 25% of the light intensity of the incident light LR is reflected back to the reflective layer 3 by the transmissive-reflective layer 5, and the reflective layer 3 reflects the 25% light intensity of the incident light LR back to the transmissive-reflective layer 5. The transmissive-reflective layer 5 transmits part of the light and reflects part of the light again. 12.5% of the light intensity of the incident light LR is reflected back to the reflective layer 3 by the transmissive-reflective layer 5, and the remaining 12.5% of the light intensity of the incident light LR can be transmitted through the transmissive-reflective layer 5, that is, the third sub-output beam LF3 is emitted from the transmissive-reflective layer 5. Since the luminous flux of the third sub-output beam LF3 overlaps with that of the second sub-output beam LF2, the first sub-output beam LF1, and the incident light LR, the light intensity of the third sub-output beam LF3 in the third region C on the side of the first surface 1 away from the second surface 2 is 75% of the light intensity of the incident light LR. The total light intensity in the third region C is the sum of the light intensity of the incident light LR, the light intensity of the first sub-output beam LF1, the light intensity of the second sub-output beam LF2, and the light intensity of the third sub-output beam LF3, that is, the total light intensity is 187.5% of the light intensity of the incident light LR. The third region C in FIG. 9 is a virtual region (shown by dashed lines), not a real region. That is, when the transmittance of the transmissive-reflective layer 5 is 50% and the reflectance is 50%, the light intensity En2 of the nth sub-output beam LFn satisfies formula (2), that is, the nth sub-output beam LFn is emitted from the transmissive-reflective layer 5 to the first surface 1 and incident on the photosensitive layer 413, where n is greater than 2. The output light LF and the incident light LR at least partially overlap and interfere on the photosensitive layer 413 of the film 41, forming alternating bright and dark interference fringes on the photosensitive layer 413. This causes the refractive index distribution of the photosensitive layer 413 to change according to the fringes, ultimately forming a refractive index modulation grating inside the photosensitive layer 413 material, thus creating a holographic optical element.

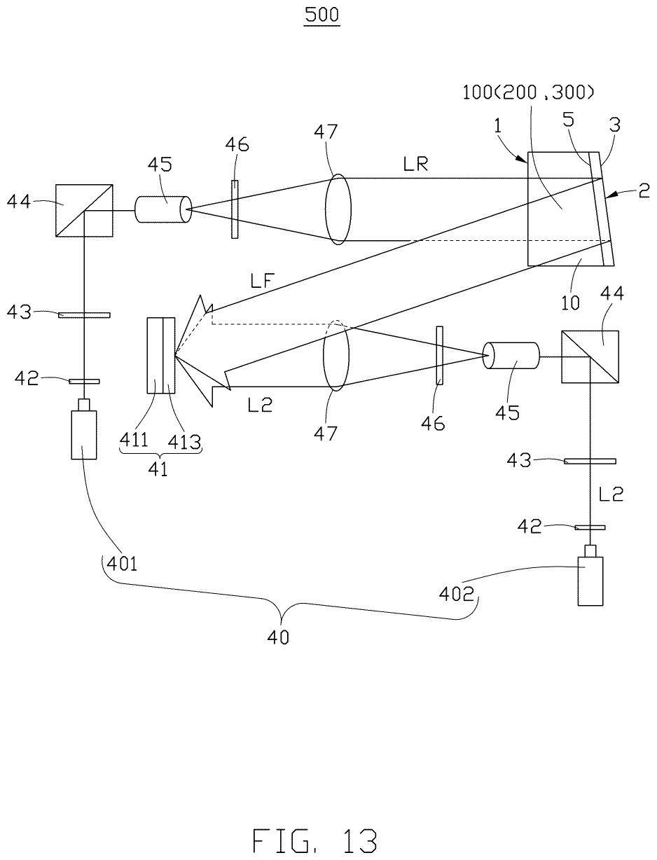

Please refer to FIG. 13. In other embodiments of the exposure system 500, the light source module 40 of the exposure system 500 further includes an auxiliary light source 402, which is used to emit auxiliary light L2. The film 41 is disposed at the intersection of the output light LF and the auxiliary light L2, and the auxiliary light L2 is incident on the film 41. The auxiliary light L2 and the output light LF interfere on the photosensitive layer 413, forming interference fringes on the photosensitive layer 413. The auxiliary light source 402 can be a gas laser, solid-state laser, semiconductor laser, fiber laser, or dye laser. In this embodiment, the first light source 401 is configured to emit the incident light LR, which is modulated by the optical element (100, 200, 300) and then emitted as output light LF from the first surface 1. Multiple sub-output beams LF0 emitted from different positions along the first direction X parallel to the first surface 1 are incident on the photosensitive layer 413, and the sub-output beams do not overlap with each other, causing the brightness of the light spot formed by the output light LF on the photosensitive layer 413 to decrease along the first direction X. In other embodiments, the first light source 401 can also be configured to emit the incident light LR, which is modulated by the optical element (100, 200, 300) and then emitted as output light LF from the first surface 1. Multiple sub-output beams LF0 emitted from different positions along the first direction X parallel to the first surface 1 are incident on the photosensitive layer 413, and the sub-output beams at least partially overlap in the first direction X, causing the brightness of the light spot formed by the output light LF on the photosensitive layer 413 to increase along the first direction X.

Please refer to FIG. 3, FIG. 11, and FIG. 13 together. The exposure system 400 (500) further includes a shutter 42, a phase retarder 43, a beam splitter 44, a spatial filter 45, an aperture stop 46, and a collimating lens 47. The shutter 42 is used to control the emission time of the incident light LR or the auxiliary light L2, that is, to control the exposure time of the exposure system 400 (500). The phase retarder 43 receives the incident light LR or the auxiliary light L2 emitted from the shutter 42, and the phase retarder 43 is used to change the polarization state of the incident light LR or the auxiliary light L2 emitted from the light source module 40, for example, changing horizontally polarized light to vertically polarized light, or changing vertically polarized light to horizontally polarized light. The beam splitter 44 receives the incident light LR or the auxiliary light L2 emitted from the phase retarder 43, and the beam splitter 44 is used to partially reflect the incident light LR or the auxiliary light L2 and partially transmit the incident light LR or the auxiliary light L2. The spatial filter 45 is used to receive the incident light LR or the auxiliary light L2 emitted from the beam splitter 44 and to remove noise from the incident light LR or the auxiliary light L2, thereby improving the beam quality of the incident light LR or the auxiliary light L2. The aperture stop 46 receives the incident light LR or the auxiliary light L2 emitted from the spatial filter 45, and the aperture stop 46 is used to adjust the spot diameter of the incident light LR or the auxiliary light L2. The collimating lens 47 is used to receive and collimate the incident light LR or the auxiliary light L2 emitted from the aperture stop 46. The incident light LR is emitted from the collimating lens 47 to the optical element (100, 200, 300), and the reflective layer 3 and the transmissive-reflective layer 5 together modulate the incident light LR into output light LF, and project the output light LF from the first surface 1. The output light LF includes multiple sub-output beams LF0 emitted from different positions of the transmissive-reflective layer 5, and the light intensity of each sub-output beam LF0 is different. The multiple sub-output beams LF0 are incident on the photosensitive layer 413. The auxiliary light L2 is emitted from the collimating lens 47 to the photosensitive layer 413. The film 41 is exposed by the light incident on the photosensitive layer 413 (the incident light LR and the auxiliary light L2), and the output light LF and the auxiliary light L2 at least partially overlap and interfere on the photosensitive layer 413 of the film 41, forming alternating bright and dark interference fringes on the photosensitive layer 413. This causes the refractive index distribution of the photosensitive layer 413 to change according to the fringes, ultimately forming a refractive index modulation grating inside the photosensitive layer 413 material, thus creating a holographic optical element. Since the multiple sub-output beams LF0 incident on the photosensitive layer 413 have different light intensities, the exposure amount at different positions on the film 41 also varies, resulting in different diffraction efficiencies at different positions of the holographic optical element. The holographic optical element is used as an out-coupling grating on the side of the optical waveguide near the human eye, and the holographic optical element is used to couple out the light transmitted by the optical waveguide, forming image light that enters the human eye. The holographic optical element with different diffraction efficiencies obtained after exposure is disposed on the output side of the optical waveguide of the AR head-mounted display device, with the end with lower diffraction efficiency away from the human eye and the end with higher diffraction efficiency close to the human eye. Since the diffraction efficiency of the holographic optical element is different at different positions, it counteracts the attenuation of light intensity on the output side, thereby improving the uneven brightness of the AR head-mounted display device.

The exposure system 400 (500) provided by the embodiments of the present disclosure, by setting the optical element (100, 200, 300) according to any of the aforementioned embodiments, allows the output light LF emitted from the first surface 1 to interfere with other light incident on the film 41. Since the sub-output beams LF0 emitted from the optical element (100, 200, 300) have different light intensities, the light incident on the film 41 also has different light intensities, meaning the exposure amount at different positions on the film 41 varies. By exposing the film 41 with the light incident on the film 41 and the sub-output beams LF0, a holographic optical element with different diffraction efficiencies at different positions can be produced. When the holographic optical element is applied to an AR head-mounted display device, the holographic optical element with different diffraction efficiencies at different positions is used as an out-coupling grating on the side of the optical waveguide near the human eye to counteract the attenuation of light intensity on the output side, thereby improving the uneven brightness of the AR head-mounted display device.

The above embodiments are only used to illustrate the technical solution of the present disclosure and not to limit the present disclosure. Although the present disclosure has been described in detail with reference to preferred embodiments, one ordinary skill in the art should understand that the technical solution of the present disclosure can be modified or equivalent replaced without departing from the spirit and scope of the technical solution of the present disclosure.

1. An optical element comprising:
a transparent substrate comprising a first surface and a second surface opposite to the first surface;
a reflective layer disposed on the second surface, the reflective layer reflecting light; and
at least one transmissive-reflective layer disposed between the reflective layer and the first surface, the at least one transmissive-reflective layer transmitting a portion of the light reflected by the reflective layer and reflecting a portion of the light reflected by the reflective layer, the reflective layer and the at least one transmissive-reflective layer cooperatively modulating incident light transmitted from the first surface into output light, and to project the output light from the first surface,
wherein different positions of the transmissive reflective layer emits multiple sub-output beams to form the output light, and a light intensity of each of the multiple sub-output beams is different.

2. The optical element of claim 1, wherein the reflective layer and the transmissive-reflective layer are arranged parallel.

3. The optical element of claim 1, wherein the second surface includes a first sub-side surface and a second sub-side surface intersecting with the first sub-side surface, the reflective layer covers the first sub-side surface and the second sub-side surface, and an angle between the first sub-side surface and the second sub-side surface ranges from 0° to 180°.

4. The optical element of claim 2, wherein the second surface is inclined relative to the first surface, and an angle between the first surface and the second surface ranges from 0° to 90°.

5. The optical element of claim 2, wherein each of the multiple sub-output beams emitted from the first surface is approximately parallel to each other, and a spacing between adjacent sub-output beams of the multiple sub-output beams is positively correlated with a distance between the reflective layer and the at least one transmissive-reflective layer.

6. The optical element of claim 1, wherein a ratio of a transmittance to a reflectance of the at least one transmissive-reflective layer ranges from 0 to 100.

7. The optical element of claim 1, the optical element is an integrally formed structure.

8. The optical element of claim 1, the transparent substrate includes several sub-transparent substrate parts, and the at least one transmissive-reflective layer and the reflective layer are respectively formed on different sub-transparent substrate parts of the several sub-transparent substrate parts, such that the at least one transmissive-reflective layer and the reflective layer are separated by the sub-transparent substrate parts, and the sub-transparent substrate parts are spliced together.

9. The optical element of claim 1, wherein when there are two or more transmissive-reflective layers, each of the at least one transmissive-reflective layer is located at a different distance from the reflective layer.

10. An exposure system comprising:
a light source module including a first light source, the first light source being used to emit incident light;
an optical element comprising:
a transparent substrate comprising a first surface and a second surface opposite to the first surface;
a reflective layer disposed on the second surface, the reflective layer reflecting light; and
at least one transmissive-reflective layer disposed between the reflective layer and the first surface, the at least one transmissive-reflective layer transmitting a portion of the light reflected by the reflective layer and reflecting a portion of the light reflected by the reflective layer, the reflective layer and the at least one transmissive-reflective layer cooperatively modulating incident light transmitted from the first surface into output light, and to project the output light from the first surface,
different positions of the transmissive reflective layer emits multiple sub-output beams to form the output light, and a light intensity of each sub-output beam is different; and
a film, disposed on one side of the optical element, the film being used to receive the output light emitted from the first surface;
wherein the optical element is used to modulate the incident light into the output light, and the output light is emitted from the first surface and projected onto the film.

11. The exposure system of claim 10, wherein the film includes a substrate and a photosensitive layer disposed on one side of the substrate, and the photosensitive layer is used to receive the output light.

12. The exposure system of claim 11, the first light source is configured to emit the incident light, which is modulated by the optical element and then emitted as output light from the first surface, the multiple sub-output beams emitted from different positions along a first direction parallel to the first surface incident on the photosensitive layer, and the multiple sub-output beams at least partially overlap in the first direction, causing the brightness of the light spot formed by the output light on the photosensitive layer to increase along the first direction.

13. The exposure system of claim 11, wherein the first light source is configured to emit the incident light, which is modulated by the optical element and then emitted as output light from the first surface, the multiple sub-output beams emitted from different positions along a first direction parallel to the first surface incident on the photosensitive layer, and the sub-output beams do not overlap with each other, causing the brightness of the light spot formed by the output light on the photosensitive layer to decrease along the first direction.

14. The exposure system of claim 11, wherein the incident light and the output light emitted from the first surface interfere on the photosensitive layer, forming interference fringes on the photosensitive layer.

15. The exposure system of claim 11, wherein the light source module further includes an auxiliary light source, the auxiliary light source being used to emit auxiliary light, the auxiliary light being incident on the film, and the auxiliary light and the output light interfere on the photosensitive layer, forming interference fringes on the photosensitive layer.
